(19) United States
(12) Patent Application Publication
(10) Pub. No.: US 2015/0103514 A1
(43) Pub. Date: Apr. 16, 2015

(54) MONOCHROMATIC DYNAMICALLY-TONAL STEREOLITHOGRAPHIC IMAGES AND METHODS OF PRODUCTION THEREOF

(71) Applicant: Dave White, Pawtucket, RI (US)

(72) Inventor: Dave White, Pawtucket, RI (US)

(21) Appl. No.: 14/512,406

(22) Filed: Oct. 11, 2014

Related U.S. Application Data
(60) Provisional application No. 61/890,174, filed on Oct. 11, 2013.

(51) Int. Cl. G03F 7/00; F21V 21/00; B29C 67/00

(52) U.S. Cl. CPC G03F 7/0037; B29C 67/0066; B29C 67/0088; F21V 21/00; B33Y 10/00
USPC 362/97.4; 264/401; 425/174.4; 428/195.1; 428/201

(57) ABSTRACT

The present invention is directed to a novel and inventive presentation form of a digital image, prepared by advancement in three-dimensional additive printing manufacture technique, e.g., stereolithographic or Polyjet printing. In particular, the present invention provides three-dimensional presentation forms with dynamic tonal definition derived from two dimensional images, as well as the methods of producing such images using a three-dimensional additive printing manufacture technique enhanced with image dependent advanced contrast technology.

### RELATED APPLICATIONS

This application is a US Utility Application that claims the benefit of priority from U.S. Provisional Patent Application No. 61/890,174, filed on Oct. 11, 2013, the entirety of which is incorporated herein by reference.

### BACKGROUND OF THE INVENTION

Photography, and methods of capturing images, have continually evolved as an art and a science. In fact, production of photographic images has advanced in step with the technology, and the creativity and artistry of presenting these images has increasing utilized digital imaging. Such digital imaging, developed in the 1960s and 1970s largely to avoid the weaknesses of film cameras for scientific and military objectives, has become more accessible to the general public. And as this digital technology has become less expensive in the decades that have followed, it has replaced the old film methods for many purposes.

Further development of these digital images in various presentation forms have resulted in new and unique forms of these images, for example, industries based on digitally reproduced prints or even lithographs, like those produced by Thomas Kinkade, the “Painter of Light,” who utilized light accents to enhance the viewing experience of his paintings and corresponding lithographs.

Digital imaging has even further evolved into three dimensions, where images have been used to produce three-dimensional objects, through a process called stereolithography. Such 3D printing technology has been used for both prototyping and distributed manufacturing with applications in architecture, construction (AEC), industrial design, automotive, aerospace, military, engineering, civil engineering, dental and medical industries, biotech (human tissue replacement), fashion, footwear, jewelry, eyewear, education, geographic information systems, and food.

However, the limitations of digital imaging, and new forms of presentation, have yet to be achieved. New industries based on novel and inventive presentation forms remain yet to be discovered, and will be welcomed to the commercial market.

### SUMMARY OF THE INVENTION

The present invention provides a novel and inventive presentation form of a digital image, prepared by advancement in three-dimensional additive printing manufacture technique, e.g., stereolithographic or Polyjet printing. In particular, the present invention provides three-dimensional presentation forms with dynamic tonal definition derived from two dimensional images, as well as the methods of producing such images using a three-dimensional additive printing manufacture technique enhanced with image dependent advanced contrast technology.

Accordingly, in one aspect, the present invention is a monochromatic dynamically-tonal stereolithographic (DTS) images.

In another aspect, the present invention provides a method of preparing a monochromatic dynamically-tonal stereolithographic (DTS) image. The method comprises the steps of enhancement of a photographic image using image dependent advanced contrast technology; processing the enhanced photographic image to generate an enhanced STL file from the processed image; printing a monochromatic DTS image precursor from the enhanced STL file; and cleaning the monochromatic DTS image precursor, such that a monochromatic DTS image is prepared.

In an additional aspect, the present invention provides an image manufacturing tool. The image manufacturing tool comprises a machine readable medium having instructions stored thereon for execution by a processor to perform a method comprising the steps of enhancement of a photographic image using image dependent advanced contrast technology; processing the enhanced photographic image to generate an enhanced STL file from the processed image; printing a monochromatic DTS image precursor from the enhanced STL file; and cleaning the monochromatic DTS image precursor, such that a monochromatic DTS image is prepared.

### BRIEF DESCRIPTION OF FIGURES

FIGS. 1A, 1B and 1C are black and white renderings of color photographic images that depict a successfully prepared monochromatic DTS image. FIG. 1A depicts the monochromatic DTS image without backlighting; FIG. 1B depicts the monochromatic DTS image with backlighting from natural window lighting; and FIG. 1C depicts the original 2-D photographic image from which the monochromatic DTS image was derived.

FIGS. 2A and 2B are black and white renderings of color photographic images that depict an unsuccessfully prepared monochromatic DTS image. FIG. 2A depicts the printed image with backlighting from natural window lighting; and FIG. 2B depicts the original 2-D photographic image from which the printed image was derived.

FIGS. 3A and 3B are black and white renderings of color photographic images that depict a successfully prepared monochromatic DTS image. FIG. 2A depicts the monochromatic DTS image with backlighting from natural window lighting; and FIG. 2B depicts the original 2-D photographic image from which the monochromatic DTS image was derived.

### DETAILED DESCRIPTION OF THE INVENTION

The present invention is directed to monochromatic dynamically-tonal stereolithographic (DTS) images, and novel preparations thereof using advanced three-dimensional additive printing manufacture techniques, e.g., stereolithographic or Polyjet printing. In particular, the present invention provides unique and surprisingly rich three dimensional imagery from a two dimensional digital image not previously seen or obtainable, through the use of image dependent advanced contrast technology,

The present invention, including monochromatic dynamically-tonal stereolithographic (DTS) images, and methods of preparation thereof, will be described with reference to the following definitions that, for convenience, are set forth below. Unless otherwise specified, the below terms used herein are defined as follows:

### I. DEFINITIONS

As used herein, the term “a,” “an,” “the” and similar terms used in the context of the present invention (especially in the context of the claims) are to be construed to cover both the singular and plural unless otherwise indicated herein or clearly contradicted by the context.

The term “additive printing” is art-recognized, and is used herein to describe a process of making a three-dimensional solid object of virtually any shape from a digital model using an additive process, where successive layers of material are laid down in different shapes. In a particular embodiment, the additve printing is Polyjet printing. In a particular embodiment, the additve printing is stereolithographic printing.

The term “clean” is used herein to describe the process of cleaning off all of the support material' encasing the final print. This can be done in a wide variety of ways including the use of solvents, hand tools, wire brushes, water-picks, and sand blasters.

The language “monochromatic DTS image precursor” is used herein to describe a cured monochromatic DTS image that has not yet been cleaned.

The language “machine-readable medium” is art-recognized, and describes a medium capable of storing data in a format readable by a mechanical device (rather than by a human). Examples of machine-readable media include magnetic media such as magnetic disks, cards, tapes, drums, punched cards and paper tapes, optical disks, barcodes, magnetic ink characters, and solid state devices such as flash-based, SSD, etc. Common machine-readable technologies include magnetic recording, processing waveforms, and barcodes. In particular embodiments, the machine-readable device is a solid state device. Optical character recognition (OCR) can be used to enable machines to read information available to humans. Any information retrievable by any form of energy can be machine-readable. Moreover, any data stored on a machine-readable medium may be transferred by streaming over a network.

The term “monochromatization” describes the process of taking a digital image and ensuring, e.g., through certain processing parameters, that the digital image is monochromatic.

The term “monochromatic” is art-recognized to describe having or consisting of one color or hue. In the present invention, the term monochromatic relates to the view of the DTS images by a viewer positioned to see the backlit image, i.e., once light as already passed through the monochromatic DTS image. However, variations in tone falling within a certain color or hue are still considered monochromatic.

The term “printing” as used herein involves translating the STL file image into a physical three dimensional object.

The language “rear light enhancement” describes directed artificial light useful with the monochromatic DTS images of the present invention.

The term “STL” is art-recognized, and is used herein to describe StereoLithography, a file format native to the stereolithography CAD software created by 3D Systems. STL is also known as Standard Tessellation Language. But in either case, “STL” is supported by many other software packages; it is widely used for rapid prototyping and computer-aided manufacturing. STL files describe only the surface geometry of a three dimensional object without any representation of color, texture or other common CAD model attributes.

The term “storing” describes the process of saving, e.g., a digital image, on a machine readable medium.

The term “tessellation,” as used In computer graphics, describes the organization of information needed to render to give the appearance of the surfaces of three-dimensional objects, e.g., realistic three-dimensional objects.

### II. MONOCHROMATIC DTS IMAGES OF THE INVENTION

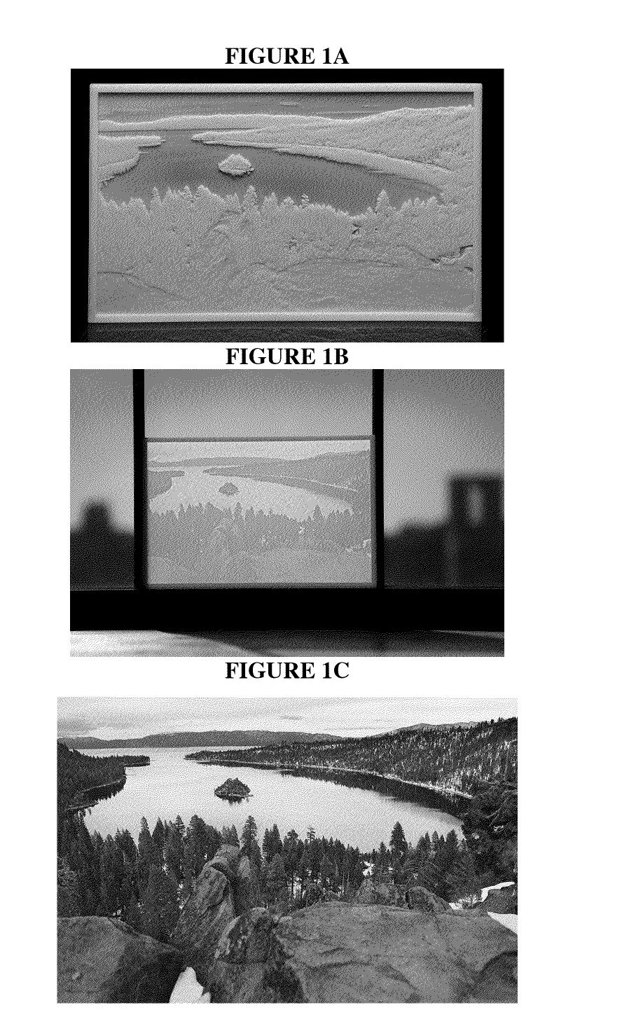

One embodiment of the present invention provides a monochromatic dynamically-tonal stereolithographic (DTS) image. A monochromatic DTS image is three dimensional representation of a two dimensional image presented by using dynamic tonal distinction through material thickness, wherein such tonal distinction is developed using advanced contrast technology described herein. An example of such an image may be found in Example 1, FIG. 1B.

The monochromatic DTS images are prepared by image dependent monochromatization using advanced contrast technology, according to the methods described herein. In the production of monochromatic DTS images, the material selection is based on the ability for the material to achieve certain translucent character for light directed through the image from behind. For example, in certain embodiments, the materials are opaque resins possessing the ability to pass certain levels of light at defined thickness. In particular embodiments, the thickness corresponding to the tonal range is 0.02 inch to 0.12 inch.

Materials may, in certain embodiments, include liquid ultraviolet curable photopolymer “resin”. In particular embodiments, the additive printing process, as described herein, produces layers that are additively built one at a time using an ultraviolet light.

In one embodiment, the additive printing process is stereolithographic printing. For each layer, the laser beam traces a cross-section of the image pattern on the surface of the liquid resin. Exposure to the ultraviolet laser light cures and solidifies the pattern traced on the resin and joins it to the layer below. After the pattern has been traced, an elevator platform that moves the UV laser and coating blade, descends by a distance equal to the thickness of a single layer, e.g., 0.05 mm to 0.15 mm. Then, a resin-filled coating blade sweeps across the cross section of the image, coating it with fresh material; and the subsequent layer pattern may be traced on this new surface, joining the previous layer, ultimately forming an image precursor. The image precursor formed is then cleaned and cured to produce the final monochromatic DTS image, e.g., parts may be immersed in a chemical bath in order to be cleaned of excess resin and subsequently further cured in an ultraviolet oven.

In another embodiment, the additive printing process is Polyjet printing, wherein, for example, Inkjet printer systems like the Objet PolyJet system spray photopolymer materials onto a build tray in ultra-thin layers (between 16 and 30 μm) until the printing is completed. Each layer of photopolymer is cured with UV light after it is sprays, or jetted, producing fully cured prints that can be handled and used immediately, without post-curing. The gel-like support material, which is designed to support complicated geometries, is removed by hand and water jetting.

In certain embodiments, the material is a rigid general purpose, high resolution, opaque photopolymer resin, e.g., gray, black, white or blue, such as the Rigid Opaque Vero family made by Stratasys. The Rigid Opaque Vero family includes: Rigid Opaque white material (VeroWhitePlus RGD835) Rigid Opaque gray material (VeroGray RGD850) Rigid Opaque blue material (VeroBlue RGD840) Rigid Opaque black material (VeroBlackPlus RGD875). In particular embodiments, the material is VeroWhite® (VeroWhite Polyjet Resin FC-830).

In certain embodiments, the material may be comprised of material designed to increase thermal functionality, dimensional stability, strength, longevity, UV protection, and/or protection from moisture.

In certain embodiments, the monochromatic DTS image may be subsequently modified to provide additional properties to the image, e.g., for protection of the image quality or structure, using materials that do not significantly affect the quality of the image produced. In one embodiment, the monochromatic DTS image further comprises a coating of material. In specific embodiments the coating material may add UV protection of the monochromatic DTS image, protection from high temperature, or protection from moisture absorption.

In certain embodiments, the monochromatic dynamically-tonal stereolithographic (DTS) image may be back-lit in order to reveal the image tones. In one particular embodiment, ambient light, e.g., natural sunlight, may be used to backlight the monochromatic DTS image, for example, by placing the it on a window sill. In another particular embodiment, rear light enhancement may be used to backlight the monochromatic DTS image, e.g., LED back-lighting.

A. Accessory Components

In certain embodiments, the monochromatic dynamically-tonal stereolithographic (DTS) images may further comprise accessory components. For example, instead of utilizing natural light, the monochromatic DTS images may comprise a rear light enhancement to afford the light accented image. In particular embodiments the rear light enhancement comprises a frame, e.g., a custom made frame, which may contain an artificial light source, e.g., LED. Such frames may be interchangeable. In certain embodiments the rear light enhancement entity is a separate interchangeable unit, e.g., the framed structure is removable and mountable to the monochromatic DTS image.

In certain embodiments, the rear light enhancement may supply uniform light distribution, which utilizes evenly-dispersed LED backlighting, e.g., with adjustable intensity.

In certain embodiments, the backlighting can be toggled between continuous and intermittent modes. Having a unique intermittent lighting option with these frames will allow the viewer to repeatedly see the transition as the image is revealed/hidden when the back-lighting fades in and out. The duration times between which the back-lighting fades in and out may be selected and/or set as a feature of this rear light enhancement

In certain embodiments, the rear light enhancement is revealed using a slider/dimming feature that reveals or exposes the image to the artificial light to allow the viewer to repeatedly see the transition as the image is revealed/hidden when the back-lighting fades in and out.

In certain embodiments of the invention, the rear light enhancement may comprise one or more colored LEDs to produce the artificial light that backlights the image.

In certain embodiments of the invention, the rear light enhancement may comprise a colored gel through which the light passes to reach the image, ultimately altering the monochromatic color hue. Such colored gels include, but are not limited to sepia tone, red, orange, yellow, blue, or green. In particular embodiments, the gel may be positioned in an accessible slot on a custom made frame, e.g., as described herein.

In certain embodiments, the monochromatic DTS image may be positioned in a window with a hanging accessory. Such hanging accessory may comprise certain window pane mountable hangers. In particular embodiments, the hanging accessory may comprise a frame with a slider/dimming feature that reveals or exposes the image to natural light to allow the viewer to repeatedly see the transition as the image is revealed/hidden when the back-lighting fades in and out. Such slider feature may also comprise a colored gel through which the light passes to reach the image, ultimately altering the monochromatic color hue.

In certain embodiments, the custom frames designed and developed to work with the monochromatic DTS images may be wood, metal, plastic, or 3D printed frames. For example, these 3D printed frames may be printed in one piece along with the monochromatic DTS image already built in. In particular embodiments, the frame may comprise built-in mechanisms: to hang the image in a window easily, to prop the image up and display on a flat surface, e.g., a desk in front of a light, or frames which could modify the LED light in a non-conventional way, e.g., moving gears built into the frame which are attached to a rotating dimming knob, e.g., wherein since all gears move when one is rotated, the LED dimming knob could be rotated (light intensity could be modified) by moving one piece of the gear ‘puzzle’, e.g., a 3D printed functional gear.

### III. METHODS OF THE INVENTION

Another embodiment of the present invention provides a method of preparing a monochromatic dynamically-tonal stereolithographic (DTS) image comprising the steps of

enhancement of a photographic image using image dependent advanced contrast technology;

processing the enhanced photographic image to generate an enhanced STL file from the processed image;

printing a monochromatic DTS image precursor from the enhanced STL file; and

cleaning the monochromatic DTS image precursor,

such that a monochromatic DTS image is prepared.

The photographic image (i.e., the two dimensional photograph) selected may be derived from any source capable of supplying a digital image, including but not limited to any machine readable medium meant to store the image, e.g., memory cards, digital cameras, mobile phones, computers, hard drives (e.g., internal or external), or internet server, as well as those that are able to convert a physical photograph into a digital image, such as scanners (e.g., used in scanning a physical photograph).

In certain embodiments, the photographic image is analyzed to ensure proper exposure, and determine if any modification, e.g., retouching, is required in order to arrive at the best possible final monochromatic DTS image.

As such, in certain embodiments, the method of preparing a monochromatic dynamically-tonal stereolithographic (DTS) image further comprises the precursor steps of

selection of the photographic image; and

analysis of the photographic image. In particular embodiments, the selection may comprise importing the photographic image from an image source to a server. In particular embodiments, the source of the photographic image is a photographic image created by the processing software (e.g., as described herein below). In particular embodiments, the photographic image is selected from machine readable medium meant to store the image, e.g., memory cards, digital cameras, mobile phones, computers, hard drives (e.g., internal or external), or internet server, as well as those that are able to convert a physical photograph into a digital image, such as scanners (e.g., used in scanning a physical photograph).

A. Enhancement of the Photographic Image

The selected photographic image, e.g., edited photographic image, is then converted into a black and white image using photo editing computer programmable instructions, e.g., software, e.g., such as Photoshop™. Such instructions provide a function that allows each color channel (RGB) to be adjusted independently, to achieve an appropriate tonal range, e.g., through the Channel Mixer of Photoshop™. Once the image has been converted to monochromatic, e.g., black and white, adjustments to the exposure and contrast are then made using photo editing computer programmable instructions, e.g., using the Curves and Levels tools of Adobe™ respectively, and the image is then reevaluated.

It is important to note that just because an image is successful when viewed in color, does not ensure that it will be as compelling in monochromatic form, e.g., black and white, since different colors can have similar grayscale values when the photograph is converted to a monochromatic image. Moreover, when the photograph is converted to a three dimensional file, areas of the image that have the same or similar grayscale value, will subsequently have the same thickness, resulting in a lack of variation and significant detail loss in the final monochromatic DTS image.

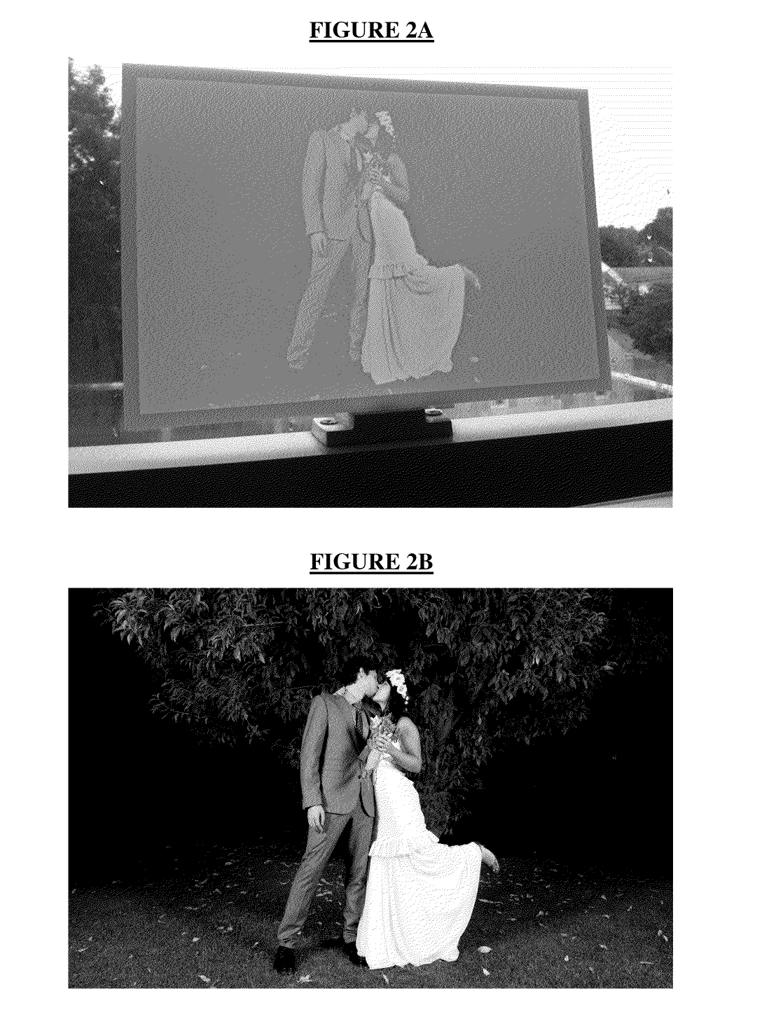

Moreover, adjustments to the exposure play an important role in the production of the final monochromatic DTS image. If areas of the photograph are underexposed, then the final monochromatic DTS image will be too thick, and if the photograph is overexposed then the final monochromatic DTS image will be too thin; each of which would result in lack of variation and significant detail loss in the final monochromatic DTS image. For example, FIG. 2A show an image where the background was underexposed, and lacked the necessary grayscale tonal range for a successful monochromatic DTS image. The resulting 3D printed image was too thick, and therefore did not allow a sufficient amount of light to pass through the thickest parts of the print.

However, this detail loss for the final monochromatic DTS image is overcome by the methods of the present invention through the use of image dependent advanced contrast technology. This technology analyzes and detects the exposure and tonal range of the monochromatic photographic image, and selectively readjusts exposure levels and tones to produce a final monochromatic photographic image that balances exposure and tonal grayscale value variation throughout the entire image, e.g., the number of tones with a similar grayscale value is reduced. In particular embodiments, the number of tones with a similar grayscale value is reduced to 0. In specific embodiments, the image dependent advanced contrast technology affords a final version of the original photograph that has a proper exposure, and an appropriate tonal range and variation, e.g., of black to white, throughout the entire image.

In certain embodiments, once the final monochromatic photographic image has been achieved through image dependent advanced contrast technology, the final image may then be cropped to desired dimensions. For example, the sizes of the monochromatic DTS images may be selected as (in inches): 5×7, 6×9, 8×10. It is important to make sure that once the image has been cropped to its final dimensions, the crucial elements of the photograph (those which make the image successful) have not been unintentionally cropped out.

B. Adjusting the Final Resolution of the Enhanced Photographic Image

In certain embodiments, the method further comprises the step of adjusting the final resolution of the enhanced photographic image prior to processing the enhanced photographic image. In certain embodiments, the final resolution of the photographic image is set to 70 to 170 dots per inch, e.g., 70 to 100 dots per inch, e.g., 72 dots per inch (dpi). It is important to note that, in order to achieve the best possible results, the editing of the original photograph should be completed before it is converted to low-resolution (e.g., 72-Dpi). Lowering the resolution of the image before converting it to 3D increases the utility of the file by reducing the overall size of the file, i.e., converting a high-resolution photograph to a 3 dimensional file would result in a very large file size that may be more difficult to work with.

C. Processing the Enhanced Photographic Image

The enhanced photographic image, e.g., with resolution adjusted, is processed to set the dimension parameters of a three dimensional rendering of the two dimensional photographic image, and to generate a 3D print-ready file, i.e., an STL file.

This processing of the enhanced photographic image may be achieved using computer programmable instructions, e.g., software, e.g., such as a program called Processing available as open source software. In certain embodiments, the image size is between 0.3 megabytes and 1 megabyte. The processing parameters of the enhanced photographic image that are modified include, for example, the size of the picture and the thickness and the extrusion distances. In certain embodiments, the maximum vertical displacement is set to 0.1″ and the base thickness is set to 0.02″. This will deliver a file with darkest areas up to 0.12″ thick and thinnest areas down to 0.02″ in thickness; wherein the thicker and thinner areas are determined by their grayscale value. The brightest colors will be 0.02″, darkest colors will be 0.12″, and the values in between will be assigned thicknesses, e.g., automatically, based on the grayscale value. At the completion of this processing, an enhanced STL file is generated.

In certain embodiments, this STL file may be modified further using computer programmable instructions, e.g., software, e.g., such as a program called Rhino available from Robert McNeel and Associates, to include an image border or image framing, which is to be merged with the STL file image into one solid. In certain embodiments, these instructions provide for a means of importing the STL file into another file type, e.g., into a Rhino file, which has default mesh framing pre-built for standard sized pictures, e.g., 5×7, 6×9 and 8×10 inches. In particular embodiments, there are landscape and/or portrait orientations for each size. Once the picture is centered in the correct framing, the two are joined as a single three dimensional image, e.g., exported as a single combined STL file.

Alternatively, the STL file may be modified by adding a black frame with desired dimensions to afford the border or image framing. The black border added to the image will have an equivalent effect to using software such as Rhino that merges an additional image with the existing STL file.

The correct framing size is selected for the image, using these computer programmable instructions. In certain embodiments, the thickness of each framing is set to 0.15″ to 0.25″ in order to give a darker boarder around the entire picture. In certain embodiments, the thickness of each framing is set to 0.15″ to give a darker boarder around the entire picture. In certain embodiments the width of each framing is set to 0.25″.

In particular embodiments, the file sizes are between 15 mb and 35 mb, or roughly 300,000 triangles and 700,000 triangles, depending on the picture dimensions and details.

In addition, certain 3D programs that may be utilized at various points in the methods of the present invention to afford the enhanced STL file include, for example, Rhino, Solidworks, Magics, Processing, Netfabb, Blender, Modo, Z-Brush, Sculptris, Geomagic Studio, Geomagic Design Direct, and/or Spaceclaim

D. Printing Monochromatic DTS Image Precursor

The enhanced STL file is then used to print a monochromatic DTS image precursor. The enhanced STL file is opened using computer programmable instructions, e.g., software, e.g., in the printer's own software. The printer may then take the information from the computer programmable instructions and translate it into a physical 3D print, the monochromatic DTS image precursor. In a particular embodiment, the model of 3D printer used is the Objet Connex 500™, made by Stratasys™.

In certain embodiments, the printing is additive printing, where successive layers of material are laid down in different shapes. In a particular embodiment, the additve printing is Polyjet printing. In a particular embodiment, the additve printing is stereolithographic printing.

In certain embodiments, the printer is set to “high-resolution” mode.

In certain embodiments, the material used is “VeroWhite.”.

In certain embodiments, the printing is subtractive printing, related to traditional machining techniques, which mostly relies on the removal of material by methods such as cutting, e.g., using lasers, or drilling. Such cutting and/or drilling, removes certain material to produce the image as the remainder of the material.

E. Cleaning of Monochromatic DTS Image Precursor

Once the monochromatic DTS image precursor has been completed, it is cleaned of the “support material” encasing the final image. This may be done in a wide variety of ways, including but not limited to the use of solvents, hand tools, wire brushes, water-picks, and sand blasters. The removal of the support material from the final print assists in the avoidance of undesired “sheen” across the final monochromatic DTS image.

F. Additional Steps

i. Coatings

In certain embodiments, the method further comprises the step of coating the monochromatic DTS image. For example, the coating may be selected from a heat resistant coating, a UV protective coating, or a moisture protecting coating. In particular embodiments, the coating does not reduce the quality of the image.

In one particular embodiment, once the final monochromatic DTS image has been prepared, a protective UV resistant coating is then applied to the print. The UV protectant applied to the final monochromatic DTS image will help prevent detrimental processes, such as yellowing or increases in brittle nature from occurring due to exposure to sunlight.

ii. Rear Light Enhancements

In certain embodiments, the method of preparing a monochromatic

DTS image further comprises the steps of providing rear light enhancement. In particular embodiments, the rear light enhancement comprises a frame, e.g., a custom made frame, which may contain an artificial light source, e.g., LED. Such frames may be interchangeable. In certain embodiments the rear light enhancement entity is a separate interchangeable unit, e.g., the framed structure is removable and mountable to the monochromatic DTS image.

In certain embodiments, the rear light enhancement may supply uniform light distribution, which utilizes evenly-dispersed LED backlighting, e.g., with adjustable intensity.

In certain embodiments, the backlighting can be toggled between continuous and intermittent modes. Having a unique intermittent lighting option with these frames will allow the viewer to repeatedly see the transition as the image is revealed/hidden when the back-lighting fades in and out. The duration times between which the back-lighting fades in and out may be selected and/or set as a feature of this rear light enhancement

In certain embodiments, the rear light enhancement is revealed using a slider/dimming feature that reveals or exposes the image to the artificial light to allow the viewer to repeatedly see the transition as the image is revealed/hidden when the back-lighting fades in and out.

In certain embodiments of the invention, the rear light enhancement may comprise one or more colored LEDs to produce the artificial light that backlights the image.

In certain embodiments of the invention, the rear light enhancement may comprise a colored gel through which the light passes to reach the image, ultimately altering the monochromatic color hue. Such colored gels include, but are not limited to sepia tone, red, orange, yellow, blue, or green. In particular embodiments, the gel may be positioned an accessible slot on a custom made frame, e.g., as described herein.

In certain embodiments, the monochromatic DTS image may be positioned in a window with a hanging accessory. In particular embodiments, the method of preparing the monochromatic DTS image, further comprises positioning the monochromatic DTS image in a window. Such hanging accessory may comprise certain window pane mountable hangers. In particular embodiments, the hanging accessory may comprise a frame with a slider/dimming feature that reveals or exposes the image to natural light to allow the viewer to repeatedly see the transition as the image is revealed/hidden when the back-lighting fades in and out. Such slider feature may also comprise a colored gel through which the light passes to reach the image, ultimately altering the monochromatic color hue.

### IV. IMPLEMENTATION OF METHODS OF THE INVENTION

In certain embodiments, the process is not automated. One or more steps is performed by a human operator to produce a monochromatic DTS image.

In certain embodiments, the process is automated. In particular embodiments, the automated method is implemented using software. As such, certain embodiments of the invention provide an image manufacturing tool comprising a machine readable medium having instructions stored thereon for execution by a processor to perform a method comprising the steps of:

enhancement of a photographic image using image dependent advanced contrast technology;

processing the enhanced photographic image to generate an enhanced STL file from the processed image;

printing a monochromatic DTS image precursor from the enhanced STL file; and

cleaning the monochromatic DTS image precursor, such that a monochromatic DTS image is prepared. In particular embodiments of the image manufacturing tool, the method further comprises the step of adjusting the final resolution of the enhanced photographic image prior to processing the enhanced photographic image. In particular embodiments of the image manufacturing tool, the method further comprises the precursor steps of selection of the photographic image; and analysis of the photographic image.

The machine-readable media described herein may be selected from the group consisting of magnetic media, punched cards, paper tapes, optical disks, barcodes, magnetic ink characters, and solid state devices (e.g., flash-based, SSD, etc.). For example, in a particular embodiment, the machine-readable medium is a solid state device. In certain embodiments, the machine-readable medium is selected from the group consisting of magnetic media, optical disks, and solid state devices.

Moreover, the instructions stored on the machine-readable medium may be implemented by online software or offline software. In certain embodiments, the instructions stored on the machine-readable medium are online software. In certain embodiments, the software is an online application, e.g., a web-based application or a cloud-based application. In certain embodiments, the software is an offline application, e.g., Software as a Service (SaaS). For example, desktop software may interact directly with internet server (e.g., without the need for a browser such as the World Wide Web)

In certain embodiments, the instructions stored on the machine-readable medium are mobile application software.

### EXEMPLIFICATION

The present invention is illustrated by the following examples, which are not intended to be limiting in any way.

### Example 1

This example presents the successful preparation of a monochromatic DTS image, i.e., FIG. 1A, from a two dimensional photographic image employing the process described herein. For clarity and visibility of detail, FIG. 1B, depicts the monochromatic DTS image with backlighting from natural window lighting.

The monochromatic DTS image precursor was printed from the enhanced STL file on a Polyjet printer, an Objet Connex 500™ made by Stratasys™, using VeroWhite Polyjet Resin after enhancement of the photographic image of FIG. 1C through image dependent advanced contrast technology and processing the enhanced photographic image to generate an enhanced STL file from the processed image. The monochromatic DTS image of FIG. 1A was produced after cleaning the monochromatic DTS image precursor was performed.

### Example 2

### Image Dependent Advanced Contrast Technology

A. Unsuccessful Attempt of Low Exposure Photographic Image

This example presents the unsuccessful attempt at preparation of a monochromatic DTS image (with full tonal detail), i.e., FIG. 2A, from a two dimensional photographic image. For clarity and visibility of detail, FIG. 2A, depicts the printed image with backlighting from natural window lighting.

The printed image was printed from an STL file on a Polyjet printer, an Objet Connex 500™ made by Stratasys™, using VeroWhite Polyjet Resin after direct generation of an STL file from the photographic image of FIG. 2B. The printed image of FIG. 2A was produced after cleaning was performed.

FIG. 2A clearly indicates that the un-enhanced underexposed photographic image (i.e., not enhanced by the methods of the present invention) that generated the STL file clearly lacked the necessary grayscale tonal range for a successful monochromatic DTS image. The color image shows a tree, which is not seen in the final printed image. Viewing with a color image allows for the leaves to be seen because of a difference in saturation compared to the black background, but the grayscale value of the background and tree match too closely to provide a dynamic print, i.e., a monochromatic DTS image.

In this respect, the present invention discovered that when the photograph is converted to a three dimensional file, areas of the image that have the same or similar grayscale value, will subsequently have the same thickness, resulting in, as was evident in FIG. 2A, a lack of variation and significant detail loss in the final monochromatic DTS image. Accordingly, the present invention has highlighted the discovery that adjustments to the exposure play an important role in the production of the final monochromatic DTS image.

B. Successful Attempt of Low Exposure Photographic Image

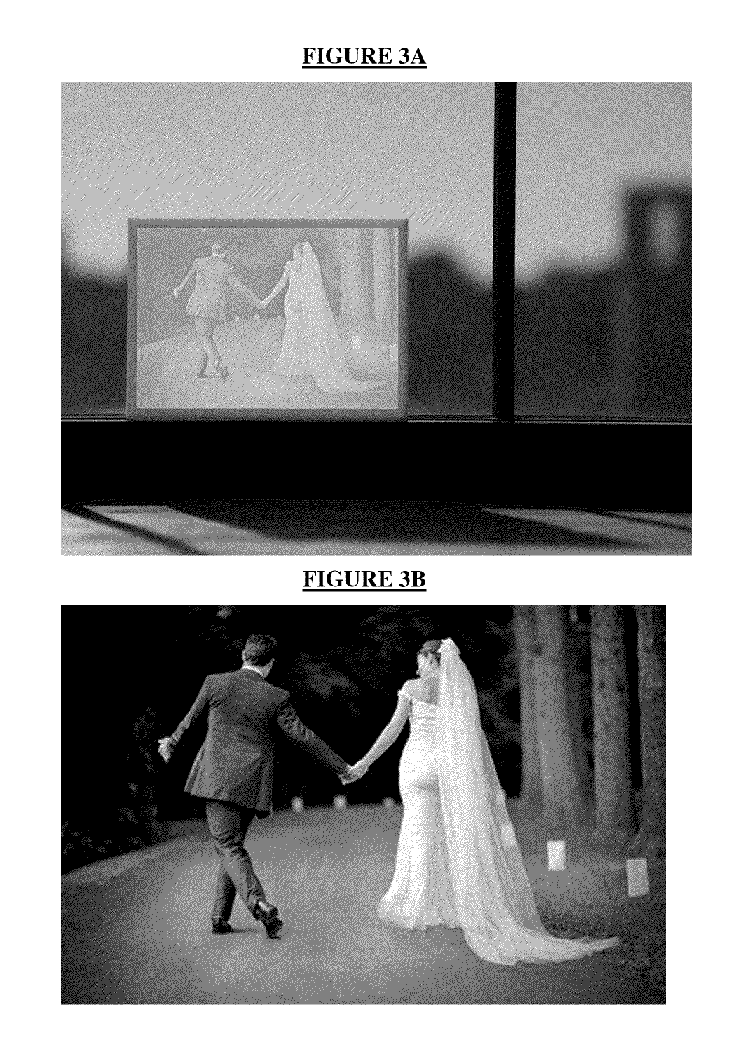

This example presents the successful attempt at preparation of a monochromatic DTS image (with full tonal detail), i.e., FIG. 3A, from a two dimensional photographic image, wherein the trees/greenery in the original 2-D photographic image had similar characteristics as the unsuccessful print above in Example 2A. For clarity and visibility of detail, FIG. 3A, depicts the monochromatic DTS image with backlighting from natural window lighting.

The monochromatic DTS image of FIG. 3A was printed from an STL file on a Polyjet printer, an Objet Connex 500™ made by Stratasys™, using VeroWhite Polyjet Resin after enhancement of the photographic image of FIG. 3B through image dependent advanced contrast technology and processing the enhanced photographic image to generate an enhanced STL file from the processed image. The monochromatic DTS image of FIG. 3A was produced after cleaning the monochromatic DTS image precursor was performed

FIG. 3A clearly indicates that the even with an underexposed photographic image, the methods of the present invention afford sufficient ability to enhance background detail to generate an STL file with the necessary grayscale tonal range for a successful monochromatic DTS image.

### INCORPORATION BY REFERENCE

The entire contents of all patents, published patent applications and other references cited herein are hereby expressly incorporated herein in their entireties by reference.

### EQUIVALENTS

Those skilled in the art will recognize, or be able to ascertain using no more than routine experimentation, numerous equivalents to the specific procedures described herein. Such equivalents were considered to be within the scope of this invention and are covered by the following claims. Moreover, any numerical or alphabetical ranges provided herein are intended to include both the upper and lower value of those ranges. In addition, any listing or grouping is intended, at least in one embodiment, to represent a shorthand or convenient manner of listing independent embodiments; as such, each member of the list should be considered a separate embodiment.

What is claimed is:

1. A monochromatic dynamically-tonal stereolithographic (DTS) image.

2. The monochromatic DTS image of claim 1 prepared by image dependent monochromatization using advanced contrast technology.

3. The monochromatic DTS image of claim 1 comprising an opaque resin possessing the ability to pass certain levels of light at defined thickness.

4. The monochromatic DTS image of claim 1 comprising VeroWhite Polyjet Resin.

5. The monochromatic DTS image of claim 1 comprising a material designed to increase one or more of the group selected from thermal functionality, dimensional stability, strength, longevity, UV protection, or protection from moisture.

6. The monochromatic DTS image of claim 1, wherein the monochromatic DTS image is subsequently modified to provide additional properties to the image.

7. The monochromatic DTS image of claim 6, wherein the monochromatic DTS image further comprises a coating of material.

8. The monochromatic DTS image of claim 7, wherein the coating material adds UV protection of the monochromatic DTS image, protection from high temperature, or protection from moisture absorption.

9. The monochromatic DTS image of claim 1 further comprising a rear light enhancement to afford a light accented image.

10. The monochromatic DTS image of claim 9, wherein the rear light enhancement comprises a frame that contains an artificial light source

11. The monochromatic DTS image of claim 10, wherein the artificial light source is an LED.

12. The monochromatic DTS image of claim 9, wherein the rear light enhancement may supply uniform light distribution, which utilizes evenly-dispersed LED backlighting,

13. A method of preparing a monochromatic dynamically-tonal stereolithographic (DTS) image comprising the steps of
enhancement of a photographic image using image dependent advanced contrast technology;
processing the enhanced photographic image to generate an enhanced STL file from the processed image;
printing a monochromatic DTS image precursor from the enhanced STL file; and
cleaning the monochromatic DTS image precursor, such that a monochromatic DTS image is prepared.

14. The method of claim 13, wherein the method further comprises the precursor steps of
selection of the photographic image; and
analysis of the photographic image.

15. The method of claim 13, wherein the method further comprises the step of coating the monochromatic DTS image.

16. The method of claim 15, wherein the coating may be selected from a heat resistant coating or a UV protective coating.

17. The method of claim 13, wherein the method of preparing a monochromatic DTS image further comprises the steps of providing rear light enhancement.

18. The method of claim 17, wherein the rear light enhancement comprises a frame that contains an artificial light source

19. The method of claim 18, wherein the artificial light source is an LED.

20. The method of claim 17, wherein the rear light enhancement may supply uniform light distribution, which utilizes evenly-dispersed LED backlighting,

21. The method of claim 18, wherein the intensity of the artificial light source is adjustable.

22. The method of claim 13, wherein the method further comprises the step of adjusting the final resolution of the enhanced photographic image prior to processing the enhanced photographic image.

23. An image manufacturing tool comprising a machine readable medium having instructions stored thereon for execution by a processor to perform a method comprising the steps of:
enhancement of a photographic image using image dependent advanced contrast technology;
processing the enhanced photographic image to generate an enhanced STL file from the processed image;
printing a monochromatic DTS image precursor from the enhanced STL file; and
cleaning the monochromatic DTS image precursor, such that a monochromatic DTS image is prepared.

24. The image manufacturing tool of claim 23, wherein the method further comprises the step of adjusting the final resolution of the enhanced photographic image prior to processing the enhanced photographic image.
